(19) United States
(12) Patent Application Publication
(10) Pub. No.: US 2019/0371916 A1
(43) Pub. Date: Dec. 5, 2019

(54) SEMICONDUCTOR STRUCTURE HAVING METAL GATE AND FORMING METHOD THEREOF

(71) Applicant: UNITED MICROELECTRONICS CORP., Hsin-Chu City (TW)

(72) Inventors: Jing-Yi Lin, Tainan City (TW); Yi-Wen Chen, Tainan City (TW); Hung-Yi Wu, Keelung City (TW); Ping-Wei Huang, Pingtung County (TW); Shao-Wei Wang, Taichung City (TW); Yueh-Chi Chuang, Tainan City (TW); Hung-Jen Huang, Tainan City (TW); Hao-Che Feng, Kaohsiung City (TW)

(21) Appl. No.: 16/018,073

(22) Filed: Jun. 26, 2018

(30) Foreign Application Priority Data
Jun. 4, 2018 (TW) 107119144

(51) Int. Cl. H01L 29/66; H01L 29/06; H01L 21/762; H01L 21/321

(52) U.S. Cl. CPC H01L 29/66545; H01L 29/0649; H01L 21/762; H01L 21/0228; H01L 29/6653; H01L 29/66553; H01L 21/3212

(57) ABSTRACT

A semiconductor structure having a metal gate includes a dielectric layer. The dielectric layer having a recess is disposed on a substrate, wherein the dielectric layer has a top part and a bottom part, and the tensile stress of the top part is larger than the tensile stress of the bottom part, thereby the recess having a sidewall profile tapering from bottom to top. The present invention also provides a method of forming said semiconductor structure.

### BACKGROUND OF THE INVENTION

### 1. Field of the Invention

The present invention relates generally to a semiconductor structure and forming method thereof, and more specifically to a semiconductor structure having a metal gate and forming method thereof.

### 2. Description of the Prior Art

Poly-silicon is conventionally used as a gate electrode in semiconductor devices, such as the metal-oxide-semiconductor (MOS). With the trend towards scaling down the size of semiconductor devices, however, conventional poly-silicon gates face problems such as inferior performance due to boron penetration and unavoidable depletion effect. This increases equivalent thickness of the gate dielectric layer, reduces gate capacitance, and worsens a driving force of the devices. Therefore, work function metals that are suitable for use as the high-K gate dielectric layer are used to replace the conventional poly-silicon gate to be the control electrode. The poly-silicon gate is formed in a dielectric layer, thereby the performance of a formed metal gate including these work function metals would being affected by the materials of the dielectric layer.

### SUMMARY OF THE INVENTION

The present invention provides a semiconductor structure having a metal gate and forming method thereof, which includes a dielectric layer having different stresses in different parts, to make a recess in the dielectric layer used for filling a metal gate have tapering sidewalls, thus shrinking the critical dimension (CD) of the metal gate.

The present invention provides a semiconductor structure having a metal gate. The semiconductor structure includes a dielectric layer having a recess disposed on a substrate, wherein the dielectric layer has a top part and a bottom part, and the tensile stress of the top part is larger than the tensile stress of the bottom part, thereby the recess having a sidewall profile tapering from bottom to top.

The present invention provides a method of forming a semiconductor structure having a metal gate including the following steps. A dielectric layer having a recess is formed on a substrate, wherein the dielectric layer has a top part and a bottom part, and the tensile stress of the top part is larger than the tensile stress of the bottom part, thereby the recess having a sidewall profile tapering from bottom to top.

According to the above, the present invention provides a semiconductor structure having a metal gate and forming method thereof, which forms a dielectric layer on a substrate, wherein the dielectric layer has a top part and a bottom part, and the tensile stress of the top part is larger than the tensile stress of the bottom part. Thereby, a recess in the dielectric layer has a sidewall profile tapering from bottom to top. In this way, the opening of the recess can be reduced, and thus the critical dimension of the top part of the metal gate formed in the recess can be reduced. Moreover, the opening of the recess and the critical dimension (CD) of the top part of the metal gate can be adjusted by changing the ratio of the top part and the bottom part in the dielectric layer. Preferably, the bottom part is formed by a flowable chemical vapor deposition process while the top part is formed by a high density plasma deposition process, thereby the tensile stress of the top part can being larger than the tensile stress of the bottom part.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a cross-sectional view of a method of forming a semiconductor structure having a metal gate according to an embodiment of the present invention.

FIG. 2 schematically depicts a cross-sectional view of a method of forming a semiconductor structure having a metal gate according to an embodiment of the present invention.

FIG. 3 schematically depicts a cross-sectional view of a method of forming a semiconductor structure having a metal gate according to an embodiment of the present invention.

FIG. 4 schematically depicts a cross-sectional view of a method of forming a semiconductor structure having a metal gate according to an embodiment of the present invention.

### DETAILED DESCRIPTION

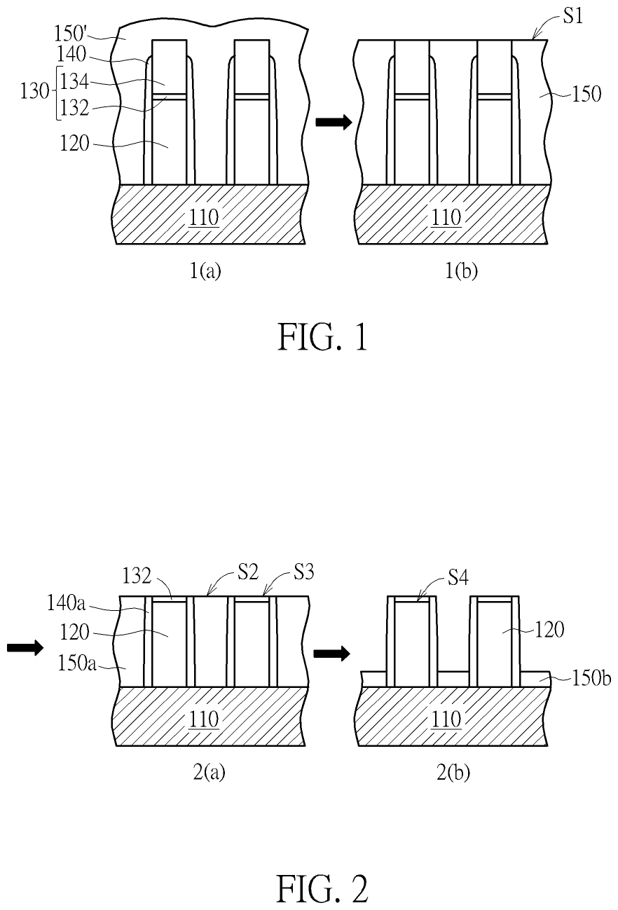

FIGS. 1-4 schematically depict cross-sectional views of a method of forming a semiconductor structure having a metal gate according to an embodiment of the present invention. As shown in FIG. 1(a), a substrate 110 may be a semiconductor substrate such as a silicon substrate, a silicon containing substrate, a III-V group-on-silicon (such as GaN-on-silicon) substrate, a graphene-on-silicon substrate, a silicon-on-insulator (SOI) substrate or a substrate containing epitaxial layers. Dummy gates 120 and hard masks 130 are formed on the substrate 110. More precisely, a dummy gate layer (not shown) and a hard mask layer (not shown) may be deposited blanketly on the substrate 110, and then the hard mask layer and the dummy gate layer are patterned to form the dummy gates 120 and the hard masks 130 stacked from bottom to top. The dummy gates 120 are composed of polysilicon, and each of the hard masks 130 may include an oxide layer 132 and a nitride layer 134, but it is not limited thereto.

Spacers 140 are formed beside the dummy gates 120 and the hard masks 130. The spacers 140 may be single spacers or dual spacers, which may be oxide spacers, nitride spacers, oxynitride spacers or oxide/nitride spacers, but it is not limited thereto. In this case, the spacers 140 are nitride spacers, and top surfaces of the spacers 140 are at the same level of sidewalls of the nitride layers 134 without protruding from the nitride layers 134. In one case, methods of forming the spacers 140 may include a spacer layer (not shown) conformally covering the dummy gates 120, the hard masks 130 and the substrate 110, and then the spacer layer (not shown) being patterned to form the spacers 140.

As shown in FIG. 1(a)-FIG. 1(b), a bottom part material 150 is formed on the substrate 110, wherein the bottom part material 150 has a flat top surface S1. More precisely, a bottom part material 150′ blanketly covers the dummy gates 120, the hard masks 130, the spacers 140 and the substrate 110, as shown in FIG. 1(a). In this embodiment, the bottom part material 150′ may be deposited by a flowable chemical vapor deposition (FCVD) process, but it is not limited thereto. Then, the bottom part material 150′ is planarized until the hard masks 130 are exposed by a method such as a chemical mechanical polishing (CMP) process, and thus the bottom part material 150 is formed, as shown in FIG. 1(b). In this embodiment, the chemical mechanical polishing (CMP) process has high selectivity to the bottom part materials 150′ and the hard masks 130. That is, the etching rate of the chemical mechanical polishing (CMP) process to the bottom part material 150′ is much larger than the etching rate of the chemical mechanical polishing (CMP) process to the hard masks 130. Thus, the hard masks 130 are stop layers, and the bottom part material 150′ is planarized until the hard masks 130 are exposed. The bottom part material 150 may be an oxide layer, but it is not limited thereto.

As shown in FIG. 2(a)-FIG. 2(b), the bottom part material 150 is planarized and then etched back. The nitride layers 134, and the bottom part material 150 and the spacers 140 at the same level as the nitride layers 134 are removed by processes such as a planarization process, thereby a bottom part material 150a and spacers 140a being formed, as shown in FIG. 2(a), wherein a top surface S2 of the bottom part material 150a is at a same level as top surfaces S3 of the oxide layers 132. Then, the bottom part material 150a is etched back to form a bottom part 150b, which is between the dummy gates 120 and is entirely lower than top surfaces S4 of the dummy gates 120. In a preferred embodiment, the bottom part material 150a is etched back by a pre-clean (SiCoNi) process, but it is not limited thereto.

As shown in FIG. 3(a)-FIG. 3(b), a top part 160 is deposited on the bottom part 150b beside the dummy gates 120 by a high density plasma deposition process. A shown in FIG. 3(a), a top part material 160′ is deposited to blanketly cover the dummy gates 120 and the bottom part 150b. Then, the top part material 160′ is planarized until a top surface S5 of the top part 160 being at a same level as the top surfaces S4 of the dummy gates 120. In one case, the top part material 160′ is planarized and the oxide layers 132 are removed by a chemical mechanical polishing (CMP) process until the dummy gates 120 are exposed. In this embodiment, the top part material 160′ is an oxide layer while the oxide layers 132 has common materials, therefore the top part material 160′ and the oxide layers 132 can be removed by a chemical mechanical polishing (CMP) process serving the dummy gates 120 as stop layers. That is, the etching rates of the chemical mechanical polishing (CMP) process to the top part material 160′ and the oxide layers 132 are much larger than the etching rate of the chemical mechanical polishing (CMP) process to the dummy gates 120. In this way, a dielectric layer D can be formed, and the dielectric layer D has the top part 160 and the bottom part 150b. In this case, the dielectric layer D is an interdielectric layer, which may be an oxide layer, and the top part 160 and the bottom part 150b are formed by different processes, so that the top part 160 and the bottom part 150b have different tensile stresses.

The top part material 160′ is preferably deposited by a high density plasma deposition process, so that the tensile stress of the top part 160 can be larger than the tensile stress of the bottom part 150b, which is formed by a flowable chemical vapor deposition (FCVD) process. Thereby, the openings of later formed recesses in the dielectric layer D can be adjusted. On the other aspect, the density of the top part 160 is larger than the density of the bottom part 150b, thus the tensile stress of the top part 160 being larger than the tensile stress of the bottom part 150b.

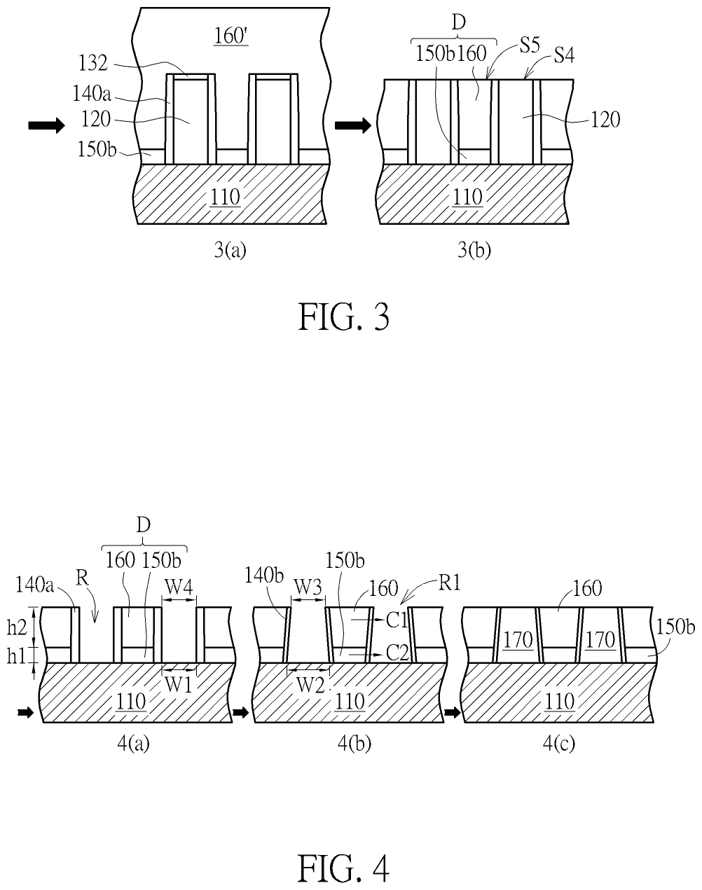

As shown in FIG. 4(a)-FIG. 4(c), a metal gate replacement process is performed to replace the dummy gates 120 by metal gates. As shown in FIG. 4(a), the dummy gates 120 are removed and thus recesses R in the dielectric layer D are formed. As shown in FIG. 4(b), at least parts of the spacers 140a are removed. In this case, the spacers 140a are thinned down to form spacers 140b. In a preferred embodiment, the spacers 140a are thinned down by an input/output oxide removing process. The input/output oxide removing process only removes oxide layers exposed in an input/output area such as oxide layers in the recesses R, and the spacers 140a are also thinned down. Since the tensile stress C1 of the top part 160 is larger than the tensile stress C2 of the bottom part 150b, recesses R1 can be formed by the deformation of the recesses R after the spacers 140a are thinned down. These recesses R1 have sidewall profiles tapering from bottom to top. In other words, each of the recesses R has a bottom part width W1 common to a bottom part width W2 of each of the recesses R1, but an opening width W3 of each of the recesses R1 is less than an opening width W4 of each of the recesses R. Therefore, metal gates 170 formed in the recesses R1 also have sidewall profiles tapering from bottom to top, as shown in FIG. 4(c). Hence, the openings of the recesses R1 can be shrunk by applying the methods of the present invention, and the critical dimension (CD) of the top parts of the metal gates 170 can also be shrunk. A height h1 of the bottom part 150b and a height h2 of the top part 160 can be adjusted to control the openings of the recesses R1 and the critical dimension (CD) of the top parts of the metal gates 170.

To summarize, the present invention provides a semiconductor structure having a metal gate and forming method thereof, which forms a dielectric layer on a substrate, wherein the dielectric layer has a top part and a bottom part, and the tensile stress of the top part is larger than the tensile stress of the bottom part. Thereby, a recess in the dielectric layer has a sidewall profile tapering from bottom to top. In this way, the opening of the recess can be reduced, and thus the critical dimension (CD) of the top part of the metal gate formed in the recess can be reduced as well. Moreover, the opening of the recess and the critical dimension of the top part of the metal gate can be adjusted by changing the ratio of the top part and the bottom part in the dielectric layer. Preferably, the bottom part is formed by a flowable chemical vapor deposition process while the top part is formed by a high density plasma deposition process, thereby the tensile stress of the top part can being larger than the tensile stress of the bottom part. On the other aspect, the density of the top part is larger than the density of the bottom part, thus the tensile stress of the top part being larger than the tensile stress of the bottom part.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor structure having a metal gate, comprising:
a dielectric layer having a recess disposed on a substrate, wherein the dielectric layer has a top part and a bottom part, and a density of the top part is larger than a density of the bottom part, so that a tensile stress of the top part being a constant is larger than a tensile stress of the bottom part, thereby the recess having a sidewall profile tapering from bottom to top.

2. The semiconductor structure having a metal gate according to claim 1, wherein the dielectric layer comprises an interdielectric layer.

3. The semiconductor structure having a metal gate according to claim 1, wherein the dielectric layer comprises an oxide layer.

4. The semiconductor structure having a metal gate according to claim 1, wherein the density of the top part is larger than the density of the bottom part.

5. The semiconductor structure having a metal gate according to claim 1, further comprising:
a metal gate disposed in the recess.

6. A method of forming a semiconductor structure having a metal gate, comprising:
forming a dielectric layer having a recess on a substrate, wherein the dielectric layer has a top part and a bottom part, and the tensile stress of the top part is larger than the tensile stress of the bottom part, thereby the recess having a sidewall profile tapering from bottom to top.

7. The method of forming a semiconductor structure having a metal gate according to claim 6, wherein the dielectric layer comprises an interdielectric layer.

8. The method of forming a semiconductor structure having a metal gate according to claim 6, wherein the dielectric layer comprises an oxide layer.

9. The method of forming a semiconductor structure having a metal gate according to claim 6, wherein the density of the top part is larger than the density of the bottom part.

10. The method of forming a semiconductor structure having a metal gate according to claim 6, further comprising:
forming a metal gate in the recess.

11. The method of forming a semiconductor structure having a metal gate according to claim 6, wherein the method of forming the dielectric layer having the recess on the substrate comprises:
forming a dummy gate on the substrate;
depositing the bottom part on the substrate beside the dummy gate by a flowable chemical vapor deposition process;
depositing the top part on the bottom part beside the dummy gate by a high density plasma deposition process; and
removing the dummy gate.

12. The method of forming a semiconductor structure having a metal gate according to claim 11, wherein the method of depositing the bottom part and the top part comprises:
depositing a bottom part material blanketly covering the dummy gate and the substrate by the flowable chemical vapor deposition process;
planarizing and then etching back the bottom part material, thereby a top surface of the bottom part is lower than a top surface of the dummy gate;
depositing a top part material blanketly covering the dummy gate and the bottom part by the high density plasma deposition process; and
planarizing the top part material, thereby a top surface of the top part is at a same level as the top surface of the dummy gate.

13. The method of forming a semiconductor structure having a metal gate according to claim 12, wherein the bottom part material is etched back by a pre-clean (SiCoNi) process.

14. The method of forming a semiconductor structure having a metal gate according to claim 6, wherein the dielectric layer comprises a spacer constituting sidewalls of the recess, and at least a part of the spacer is removed after the dummy gate is removed.

15. The method of forming a semiconductor structure having a metal gate according to claim 14, wherein the spacer is removed while performing an input/output oxide removing process.
